(19) United States
(12) Patent Application Publication
(10) Pub. No.: US 2010/0163920 A1
(43) Pub. Date: Jul. 1, 2010

(54) SEMICONDUCTOR LIGHT EMITTING DEVICE

(75) Inventor: Junichi Itai, Kyoto (JP)

Correspondence Address: HAMRE, SCHUMANN, MUELLER & LARSON, P.C., P.O. BOX 2902, MINNEAPOLIS, MN, 55402-0902, US

(73) Assignee: Rohm Co., Ltd., Kyoto-shi (JP)

(21) Appl. No.: 12/663,990

(22) PCT Filed: Jun. 11, 2008
(86) PCT No.: PCT/JP2008/060652

§ 371 Date: Dec. 10, 2009

(30) Foreign Application Priority Data
Jun. 14, 2007 (JP) 2007-157296

(51) Int. Cl. H01L 33/00

(52) U.S. Cl. 257/99; 257/E33.066

(57) ABSTRACT

A semiconductor light emitting device (A) includes a resin package (5), a semiconductor light emitting element (4), a first lead (1A) and a second lead (1B). The resin package (5) has an upper surface and a bottom surface, and has translucency. The semiconductor light emitting element (4) is covered with the resin package (5) in a state where the semiconductor light emitting element faces the upper surface of the resin package (5). The first lead (1A) includes a bonding pad (11A) which supports the semiconductor light emitting element (4). The second lead (1B) is separated from the first lead (1A), and is electrically connected to the semiconductor light emitting element (4) via a wire (6). The leads (1A, 1B) have mounting terminals (13A, 13B) which are exposed from the bottom surface of the resin package (5). The mounting terminals (13A, 13B) are surrounded by the resin package (5) in an in-plane direction perpendicular to the thickness direction of the resin package.

### TECHNICAL FIELD

The present invention relates to a semiconductor light emitting device which is used as a light source in a mobile telephone or a dot matrix type image display device, for example.

### BACKGROUND ART

FIG. 4 shows one example of a conventional semiconductor light emitting device (see Patent Document 1 described below). The semiconductor light emitting device X shown in FIG. 4 comprises a substrate 91, a pair of electrodes 92A, 92B formed on this substrate, and an LED chip 94 which is bonded to the electrode 92A. The LED chip 94 and a bonding wire 96 are covered with a resin package 95. One of the electrodes 92A includes a bonding pad 92Aa, and the LED chip 94 is connected to this bonding pad 92Aa by means of Ag paste 93. The other electrode 92B has a bonding pad 92Ba for fixing a bonding wire 94.

Patent Document 1: Japanese Patent Application Laid-open No. 2001-196641

The semiconductor light emitting device X having the composition described above is used as a light source in a mobile phone, for example. In recent years, there has been a strong trend toward compactification of mobile telephones, and in accordance with this, more compact size has also been demanded in semiconductor light emitting devices X. However, as described below, in the conventional composition described above, there are certain limits on the amount by which the semiconductor light emitting device X can be made more compact. Specifically, the resin package 95 need be of a prescribed size so as to cover suitably the LED chip 94 and the wire 96. On the other hand, although not shown in the drawings, it is necessary to form through holes for forming the electrodes 92A and 92B in an integrated fashion on the front and rear surfaces of the substrate 91, in the end portions of the substrate 91. If these through holes are provided in positions overlapping with the resin package 95, then resin material for forming the resin package 95 leaks out from the through holes. In order to avoid a problem of this kind, the size of the substrate 91 inevitably has to be made even larger than the resin package 95 and hence compactification of the semiconductor light emitting device X is impeded.

One conceivable way of achieving a more compact size of the semiconductor light emitting device X is to make the LED chip 94 more compact in size. However, if the LED chip 94 is made small, then the bonding surface area between this chip and the bonding pad 92Aa becomes smaller and the bonding force created by the Ag paste 93 becomes weaker. As a countermeasure to this, it is possible to increase the amount of Ag paste 93 used, but in this case, the Ag paste 93 protrudes out from the LED chip 94 and is liable to spread so as to surround the LED chip 94. This surplus Ag paste 93 absorbs light emitted from the LED chip 94 and reduces the luminosity of the semiconductor light emitting device X.

The semiconductor light emitting device X can be used as a light source in a dot matrix type image display device, apart from in a mobile telephone. In this case, a plurality of semiconductor light emitting devices X are surface mounted on one circuit substrate. However, in a conventional composition, if the semiconductor light emitting devices X are soldered to a circuit substrate, then a state results in which solder fillets spread from either end face of the substrate 91. Therefore, it is necessary to increase the mounting pitch between adjacently positioned the semiconductor light emitting devices X so that there is no interference between the solder fillets, but this factor impedes reduction in the size of the image display device as a whole and improvement of the quality of the displayed image.

### DISCLOSURE OF THE INVENTION

The present invention has been proposed in view of the foregoing circumstances. It is an object of the present invention to provide a semiconductor light emitting device which is suited to achieving more compact size, higher mounting density and increased luminosity.

The semiconductor light emitting device provided by the present invention includes: a translucent resin package having an upper surface and a bottom surface; a semiconductor light emitting element which opposes the upper surface of the resin package and which is covered with the resin package; a first lead including a bonding pad for supporting the semiconductor light emitting element; and a second lead which is separated from the first lead and is electrically connected to the semiconductor light emitting element. The leads each have a mounting terminal which is exposed from the bottom surface of the resin package. Each mounting terminal is surrounded by the resin package in an in-plane direction which is perpendicular to a thickness direction of the resin package (the direction in which the upper surface and the bottom surface of the resin package are spaced from each other).

With the above arrangements, when forming the resin package, there is no problem of leaking of resin material from the through holes provided in the substrate, for example. Therefore, the dimensions of the semiconductor light emitting device can be made virtually the same as the dimensions of the resin package, and it is possible to make the semiconductor light emitting device compact in size. Furthermore, in a state where the semiconductor light emitting device has been surface mounted, the solder hardly protrudes at all from the mounting terminals. Consequently, it is possible to achieve higher density mounting of semiconductor light emitting devices.

Preferably, the semiconductor light emitting device of the present invention may further comprise an Ag plating layer which covers the bonding pad. According to this composition, it is possible to reflect the light emitted downwards from the semiconductor light emitting element, in the upward direction by means of the Ag plating layer. Therefore, it is possible to achieve higher luminosity of the semiconductor light emitting device.

Preferably, the semiconductor light emitting device of the present invention may further comprise a metal bonding layer which bonds together the semiconductor light emitting element and the Ag plating layer. The metal bonding layer can be made of an alloy containing Au. With this arrangement, it is possible securely to bond together the semiconductor light emitting element and the Ag plating layer, in a eutectic state. Furthermore, the metal bonding layer can be formed to a size whereby the layer hardly projects beyond the semiconductor light emitting element. Consequently, the light from the semiconductor light emitting element is not absorbed by the metal bonding layer, which is beneficial for achieving high luminosity of the semiconductor light emitting device.

Other characteristics and advantages of the present invention will be apparent from the following detailed description with reference to the accompanying drawings.

### BRIEF DESCRIPTION OF THE DRAWINGS

FIG. 1 is a perspective diagram showing a semiconductor light emitting device according to the present invention;

FIG. 2 is a cross-sectional diagram along line II-II in FIG. 1;

FIG. 3 is a bottom surface diagram of the semiconductor light emitting device according to the present invention; and

FIG. 4 is a cross-sectional diagram showing one example of a conventional semiconductor light emitting device.

### BEST MODE FOR CARRYING OUT THE INVENTION

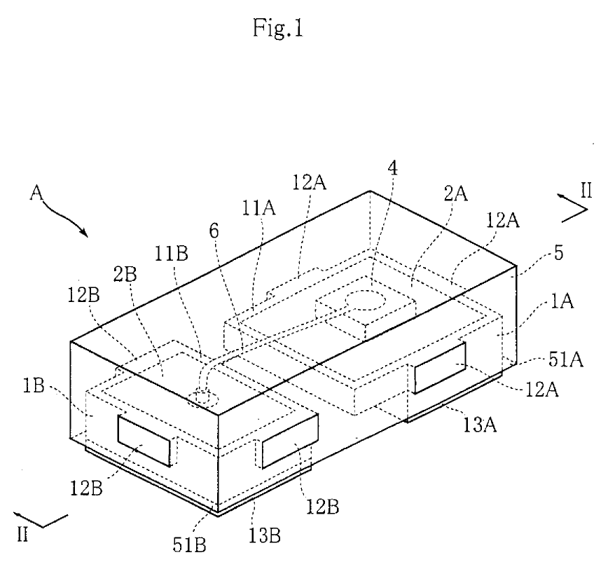

FIGS. 1-3 show a semiconductor light emitting device according to the present invention. The illustrated semiconductor light emitting device A comprises one pair of leads 1A, 1B, Ag plating layers 2A, 2B, a metal bonding layer 3, an LED chip 4, and a resin package 5. As seen from FIG. 1, in the present embodiment, the resin package 5 has a rectangular parallelepiped shape, and has an upper surface and a bottom surface which are separated in the thickness direction. Moreover, the resin package 5 has a pair of end surfaces and a pair of side surfaces which extend between the upper surface and the bottom surface. The pair of end surfaces are surfaces which are mutually separated in the lengthwise direction of the resin package 5 (the direction in which the leads 1A and 1B are mutually separated), and the pair of side surfaces are surfaces which are mutually separated in the breadthways direction of the resin package 5 (the direction which is perpendicular to both the thickness direction and the lengthwise direction). The semiconductor light emitting device A has a length of 0.6 mm, a width of 0.3 mm and a thickness of approximately 0.2 mm.

The pair of leads 1A and 1B serve to support the LED chip 4 and supply electric power to the LED chip 4. The pair of leads 1A and 1B are made of copper, for example (or an alloy containing copper), and has a thickness of approximately 0.1 mm or less. The lead 1A comprises a bonding pad 11A, three projecting sections 12A and a mounting terminal 13A. The lead 1B has a bonding pad 11B, three projecting sections 12B and a mounting terminal 13B.

The bonding pad 11A is a portion for die bonding the LED chip 4 and has a size of, for example, 0.27 mm×0.24 mm approximately. The bonding pad 11B serves to bond the wire 6 and has a size of approximately 0.19 mm×0.24 mm approximately. The bonding pad 11A and the bonding pad 11B are both covered with the resin package 5.

Projecting sections 12A and 12B project respectively in a horizontal direction from the bonding pad 11A and the bonding pad 11B. Each of the projecting sections 12A and 12B has an end surface which is exposed either on the side surface or the end surface of the resin package 5. These projecting sections 12A and 12B are produced as a result of the respective leads 1A and 1B being separated from the supporting frame when a portion of the lead frame is cut during manufacture of the semiconductor light emitting device A.

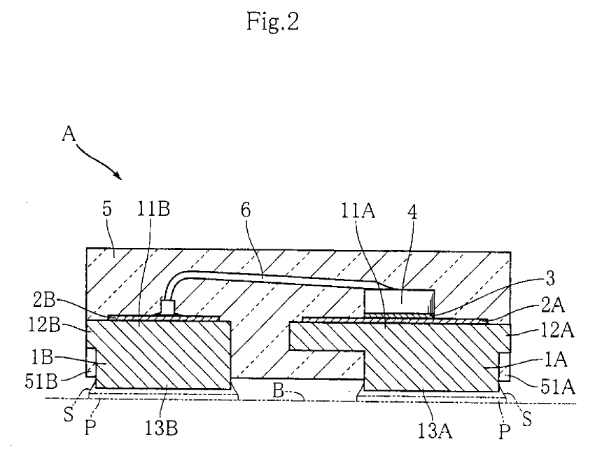

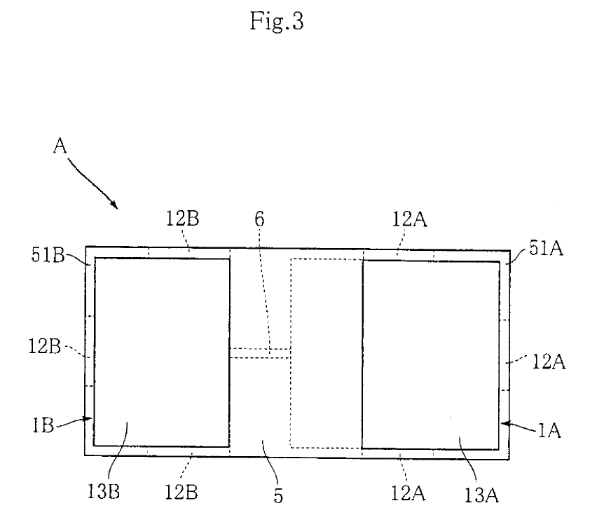

The mounting terminals 13A and 13B are used for surface mounting of the semiconductor light emitting device A on a printed substrate, or the like. As shown in FIG. 2, the leads 1A and 1B respectively have portions which are swollen in size from the bonding pad 11A and the bonding pad 11B towards the side opposite to the side where the LED chip 4 is located (the downward direction in the diagram.) The mounting terminals 13A and 13B are portions of these swollen portions which are exposed from the bottom surface of the resin package 5. As seen in FIG. 3, the mounting terminals 13A and 13B are provided at positions distanced from the edges of the bottom surface of the resin package 5. Therefore, the mounting terminals 13A and 13B have an aspect whereby they are surrounded by the frame portions 51A and 51B of the resin package in an in-plane direction (the direction which is perpendicular to the thickness direction of the leads 1A, 1B and parallel to the bottom surface of the resin package 5). As shown in FIG. 3, in the present embodiment, the main mounting surface of the mounting terminals 13A and 13B is a square shape of the same size, for example, a size of approximately 0.19 mm×0.27 mm.

The Ag plating layers 2A and 2B are layers formed by plating silver, which cover the bonding pads 11A and 11B. In the present embodiment, the size of the Ag plating layer 2A is approximately 0.25 mm×0.21 mm and the size of the Ag plating layer 2B is approximately 0.13 mm×0.2 mm.

The metal bonding layer 3 serves to bond together the LED chip 4 and the Ag plating layer 2A and is made of an alloy of any one of Sn, Si and Ge, and Au. The bond based on the metal bonding layer 3 is created by for example pressing the LED chip 4 against the Ag plating layer 2A via the metal bonding layer 3 and in this state, setting the ambient temperature to approximately 200° C. to 350° C. and then causing the LED chip 4 to vibrate by ultrasonic waves. By this means, the metal bonding layer 3 forms a eutectic state with both the Ag plating layer 2A and the LED chip 4. By means of this bond, the LED chip 4 becomes securely fixed to the bonding pad 11A. The thickness of the metal bonding layer 3 is 1 μm or less, for example.

The LED chip 4 is a light source of the semiconductor light emitting device A and is constructed by laminating together an n type semiconductor layer, a p type semiconductor layer, and sandwiched between these, an active layer. If the LED chip 4 is made of an AlGaInN type semiconductor, for example, then the chip can emit blue light. The LED chip 4 has a planar size of approximately 0.1 mm×0.1 mm, and a thickness of approximately 50 μm. The upper surface of the LED chip 4 opposes the upper surface of the resin package 5 and is connected to the Ag layer 2B of the bonding pad 11B via the wire 6.

The resin package 5 serves to protect the LED chip 4 and the bonding wire 6. The resin package 5 is formed by using an epoxy resin, for example, so as to transmit the light from the LED chip 4. A prescribed fluorescent material may also be mixed into the resin package 5. For example, by mixing a fluorescent material which emits yellow light when excited by blue light, it is possible to the semiconductor light emitting device A as a light source for white light. As stated previously, a portion of the resin package 5 forms frame sections 51A and 51B which surround the mounting terminals 13A and 13B. In the present embodiment, the resin package 5 is taken to have planar dimensions of 0.6 mm×0.3 mm approximately and a thickness of approximately less than 0.2 mm.

Next, the workings of the semiconductor light emitting device A will be described.

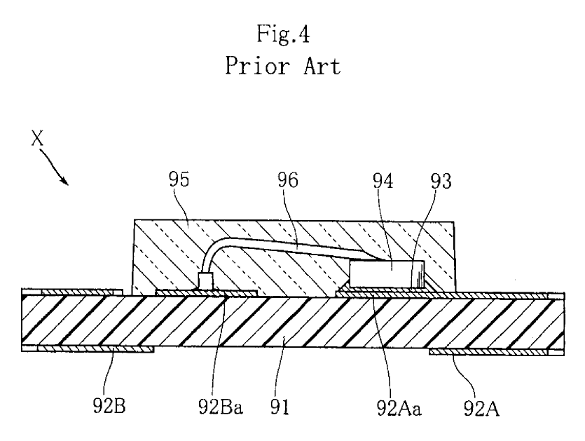

According to the embodiment described above, it is not necessary to take account of the problem of leakage of resin material which is occurs in the prior art technology shown in FIG. 4. Consequently, by making the size of the whole semiconductor light emitting device A virtually the same size as the resin package 5, it is possible to achieve a more compact size of the semiconductor light emitting device A.

Furthermore, the epoxy resin which is the material of the resin package 5 has poor wettability by solder. Therefore, as shown in FIG. 2, when the mounting terminals 13A and 13B are soldered onto the pad P formed on the circuit substrate B, the solder S adopts a form where it is retained by the frame sections 51A and 51B of the resin package 5 and hardly projects at all beyond the mounting terminals 13A and 13B. Consequently, even if a plurality of semiconductor light emitting devices A are mounted in a dense fashion on the same circuit substrate B, there is no risk of mutual interference between the solder S of the devices, and therefore good compatibility with high-definition arrangement of the dot matrix display device is achieved.

The Ag plating layer 2A forms a reflective layer of high reflectivity. Therefore, the light emitted downwards towards the bonding pad 11A from the LED chip 4 is reflected efficiently in the upward direction. By this means, it is possible to achieve higher luminosity of the semiconductor light emitting device A. In particular, if the LED chip 4 emits blue light, then the Ag plating layer 2A is especially suitable for reflecting this blue light. Moreover, providing the Ag plating layer 2B which covers the bonding pad 11B also serves to reflect a greater amount of the light emitted from the LED chip 4 in the prescribed direction. Furthermore, the heat generated by light emission by the LED chip 4 can be radiated efficiently to the circuit substrate via the bonding pad 11A and the mounting terminal 13A. This is beneficial in achieving higher luminosity of the semiconductor light emitting device A.

As stated above, by means of the metal bonding layer 3, it is possible to bond together the LED chip 4 and the Ag plating layer 2A securely in a eutectic state. Therefore, even if the LED chip 4 is compact in size, it is still possible to fix the chip securely to the Ag plating layer 2A (and hence to the bonding pad 11A). Moreover, since sufficient bonding force of the LED chip 4 is achieved, then the amount of the metal bonding layer 3 does not have to be increased to the extent of protruding out in the horizontal direction from the LED chip 4. Hence, there is no risk of the light emitted from the LED chip 4 being absorbed by the metal bonding layer 3 and it is possible further to promote increased luminosity of the semiconductor light emitting device A.

The semiconductor light emitting device based on the present invention is not limited to the embodiment described above. For example, the shape of the main mounting surface on the mounting terminals 13A and 13B is not limited to a square shape, and may also be another polygonal shape or a circular shape. The LED chip 4 is not limited to a chip which emits blue light, and may also emit lights of various wavelengths, such as red light, green light, or the like. The fluorescent material mixed into the resin package 5 should be selected appropriately in accordance with the light emitted from the LED chip 4. Alternatively, the resin package 5 may be a colorless translucent resin which does not include a fluorescent material. Using a metal bonding layer 3 to bond the LED chip 4 and the Ag plating layer 2A is desirable in increasing the bonding force and achieving high luminosity, but the present invention is not limited to this. For example, it is also possible to use an Ag paste instead of a metal bonding layer 3. The material of the metal bonding layer 3 is not limited to that described above, and may also use another alloy which can bond together the LED chip 4 and the Ag plating layer 2A in eutectic state.

1. A semiconductor light emitting device, comprising:
a translucent resin package including an upper surface and a bottom surface;
a semiconductor light emitting element opposing the upper surface of the resin package and covered with the resin package;
a first lead including a bonding pad for supporting the semiconductor light emitting element; and
a second lead separated from the first lead and electrically connected to the semiconductor light emitting element;
wherein the leads each include a mounting terminal exposed from the bottom surface of the resin package, the mounting terminal being surrounded by the resin package in an in-plane direction perpendicular to a thickness direction in which the upper surface and the bottom surface of the resin package are spaced from each other.

2. The semiconductor light emitting device according to claim 1, further comprising an Ag plating layer covering the bonding pad.

3. The semiconductor light emitting device according to claim 2, further comprising a metal bonding layer for bonding the semiconductor light emitting element and the Ag plating layer to each other, wherein the metal bonding layer is made of an alloy containing Au.
